(19) United States
(12) Patent Application Publication
(10) Pub. No.: US 2026/0247815 A1
(43) Pub. Date: Aug. 20, 2026

(54) ELECTRONIC DEVICE

(71) Applicant: Samsung Display Co., Ltd., Yogin-si (KR)

(72) Inventors: Kyeuk LEE, Yongin-si (KR); Byungseok Choi, Yongin-si (KR)

(73) Assignee: Samsung Display Co., Ltd., Yongin-si (KR)

(21) Appl. No.: 19/414,947

(22) Filed: Dec. 10, 2025

(30) Foreign Application Priority Data
Feb. 19, 2025 (KR) 10-2025-0021274

(51) Int. Cl. H10K 59/131; H10K 59/121

(52) U.S. Cl. CPC H10K 59/131; H10K 59/1213; H10K 59/1216

(57) ABSTRACT

An electronic device may include a base layer including an active area and a peripheral area, pixels in the active area, each of the pixels including a pixel circuit, a repair pixel circuit in the peripheral area, data lines connected to the pixels, and a repair line connected to the repair pixel circuit and extending to the active area. A portion of the repair line may overlap the data lines.

### CROSS-REFERENCE TO RELATED APPLICATIONS

This application claims priority under 35 U.S.C. § 119 to Korean Patent Application No. 10-2025-0021274 filed on Feb. 19, 2025, in the Korean Intellectual Property Office, the disclosure of which is incorporated by reference herein in its entirety.

### BACKGROUND

Embodiments of the present disclosure described herein relate to an electronic device including pixels with an improved reliability.

A display panel included in an electronic device includes a plurality of pixels and a driver (e.g., a scan driver and a data driver) that control the plurality of pixels. Each of the plurality of pixels includes a display element and a pixel driver that controls the display element. The driver of the pixel may include a plurality of transistors and at least one capacitor that are organically connected to each other. Data lines that are connected to the pixels need to be shielded to prevent coupling to adjacent conductive patterns.

### SUMMARY

Embodiments of the present disclosure provide an electronic device that includes a pixel with an improved reliability by utilizing a repair line for a configuration for shielding data lines.

According to one or more embodiments, an electronic device may include a base layer including an active area and a peripheral area, pixels in the active area, each of the pixels including a pixel circuit, a repair pixel circuit in the peripheral area, data lines connected to the pixels, and a repair line connected to the repair pixel circuit and extending to the active area. A portion of the repair line may overlap the data lines.

### BRIEF DESCRIPTION OF DRAWINGS

The above and other objects and features of the present disclosure will become apparent by describing in detail embodiments thereof with reference to the accompanying drawings.

FIG. 1A is a block diagram of an electronic device according to one or more embodiments.

FIG. 1B illustrates schematic views of an electronic device according to various embodiments.

FIG. 2A is a perspective view of an electronic device according to one or more embodiments of the present disclosure.

FIG. 2B is a perspective view of a curved electronic device according to one or more embodiments of the present disclosure.

FIG. 2C is a cross-sectional view of an electronic device according to one or more embodiments of the present disclosure.

FIG. 3A is a plan view of an electronic device according to one or more embodiments of the present disclosure.

FIG. 3B is an equivalent circuit diagram of a repair pixel and a pixel according to one or more embodiments of the present disclosure.

FIG. 4 is an enlarged plan view of a display area according to one or more embodiments of the present disclosure.

FIG. 5 is a plan view according to a stack order of conductive patterns included in a unit pixel according to one or more embodiments of the present disclosure.

FIG. 6 is a cross-sectional view taken along line I-I’ of FIG. 5.

FIGS. 7A to 7F are plan views illustrating a stack order of layers of conductive patterns included in a unit pixel for respective patterns according to one or more embodiments of the present disclosure.

### DETAILED DESCRIPTION

In the specification, the expression that a first component (or area, layer, part, portion, etc.) is “on”, “connected with”, or “coupled with” a second component means that the first component is directly on, connected with, or coupled with the second component or means that a third component is interposed therebetween.

The same reference numerals refer to the same components. Furthermore, in drawings, the thickness, ratio, and dimension of components are exaggerated for effectiveness of description of technical contents. The term “and/or” includes one or more combinations in each of which associated elements are defined.

Although the terms “first”, “second”, etc. may be used to describe various components, the components should not be construed as being limited by the terms. The terms are only used to distinguish one component from another component. For example, without departing from the scope and spirit of the present disclosure, a first component may be referred to as a second component, and similarly, the second component may be referred to as the first component. The articles “a,” “an,” and “the” are singular in that they have a single referent, but the use of the singular form in the specification should not preclude the presence of more than one referent.

Also, the terms “under”, “below”, “on”, “above”, and the like are used to describe the correlation of components illustrated in drawings. The terms are relative concepts, and are described with respect to directions indicated in the drawings.

It will be understood that the terms “include”, “comprise”, “have”, and the like specify the presence of features, numbers, steps, operations, elements, or components, described in the specification, or a combination thereof, not precluding the presence or additional possibility of one or more other features, numbers, steps, operations, elements, or components or a combination thereof.

Unless otherwise defined, all terms (including technical terms and scientific terms) used in the specification have the same meaning as commonly understood by one skilled in the art to which the present disclosure belongs. Furthermore, terms such as terms defined in the dictionaries commonly used should be interpreted as having a meaning consistent with the meaning in the context of the related technology, and should not be interpreted in ideal or overly formal meanings unless explicitly defined herein.

Hereinafter, embodiments of the present disclosure will be described with reference to accompanying drawings.

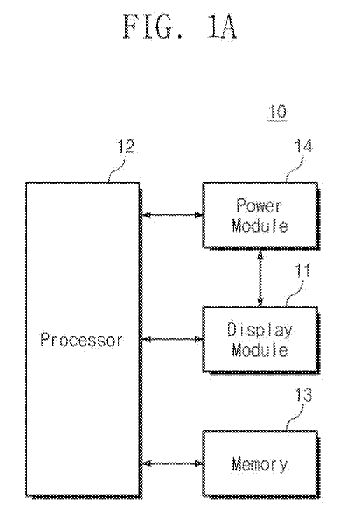

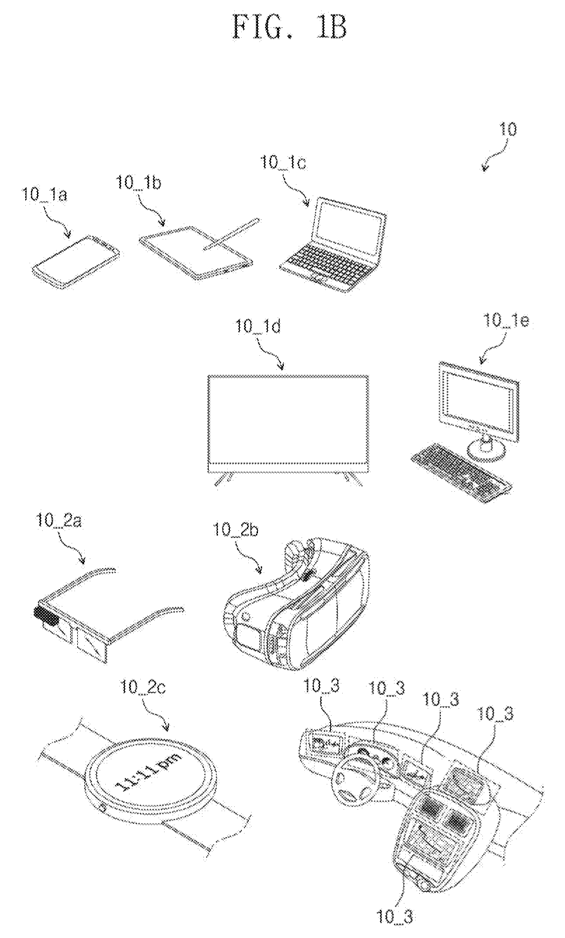

FIG. 1A is a block diagram of an electronic device according to one or more embodiments. FIG. 1B illustrates schematic views of an electronic device according to various embodiments.

FIG. 1A is a block diagram of an electronic device according to one or more embodiments. Referring to FIG. 1A, an electronic device 10 according to one or more embodiments may include a display module (e.g., a display panel or a display assembly) 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller.

Data information and/or instructions that are necessary to operate the processor 12 or the display module 11 may be stored in a memory 15. When the processor 12 executes an application stored in the memory 15, an image data signal and/or an input control signal may be transmitted to the display module 11, and the display module 11 may process the provided signal and output image information through a display screen.

The power module 14 may include a power supply module (e.g., a power supply circuit), such as a power adapter or a battery device (e.g., a battery pack), and a power conversion module (a power conversion circuit, for example, such as a DC-DC converter or AC-DC converter) that converts electric power supplied by the power supply module to generate electric power that is required for an operation of the electronic device 10.

At least one of the components of the electronic device 10 described above may be included in the display device according to the above-described embodiments. Furthermore, some of the individual modules that are functionally included in one module may be included in the display device, and others may be provided separately from the display device. For example, the display device includes a display module 11, and the processor 12, the memory 13, and the power module 14 may be provided in the form of other devices in the electronic device 10 rather than the display device.

FIG. 1B illustrates schematic views of an electronic device according to various embodiments.

Referring to FIG. 1B, various electronic device, to which the displays according to embodiments is applied, may include not only an electronic device for displaying an image, such as a smartphone 10_1a, a tablet PC 10_1b, a laptop computer 10_1c, a TV 10_1d, and a monitor 10_1e for a desk, and but also a wearable electronic device including a display module, such as smart glasses 10_2a, a head-mounted display 10_2b, and a smart watch 10_2c, and an electronic device 10_3 for a vehicle including a display module, such as a center information display disposed in an instrument panel for a vehicle, a center fascia, and a dash board, and a room mirror display.

The display device/display panel according to one or more embodiments may be applied to various electronic devices. The electronic device according to one or more embodiments includes the above-described display device/display panel, and may further include a module or device having other additional functions, in addition to that of the display device/display panel.

Hereinafter, an electronic device to be described in the drawings may be applied to embodiments of the above-described electronic devices.

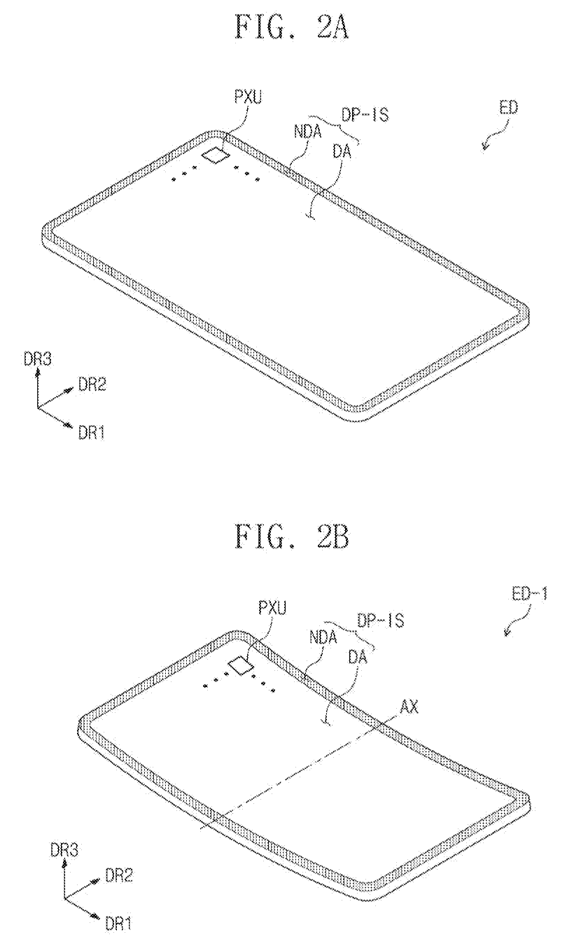

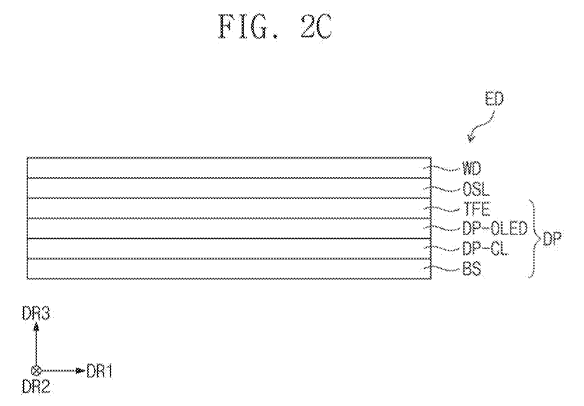

FIG. 2A is a perspective view of an electronic device according to one or more embodiments of the present disclosure. FIG. 2B is a perspective view of a curved electronic device according to one or more embodiments of the present disclosure. FIG. 2C is a cross-sectional view of an electronic device according to one or more embodiments of the present disclosure.

A electronic device ED according to one or more embodiments may include a display surface DP-IS. The display surface DP-IS may be parallel to a surface that is defined by a first direction DR1 and a second direction DR2. A normal direction of the display surface DP-IS, that is, a thickness direction of a display panel DP, indicates a third direction DR3. Front surfaces (or upper surfaces) and rear surfaces (or lower surfaces) of the layers or unit that will be described later are divided by the third direction DR3.

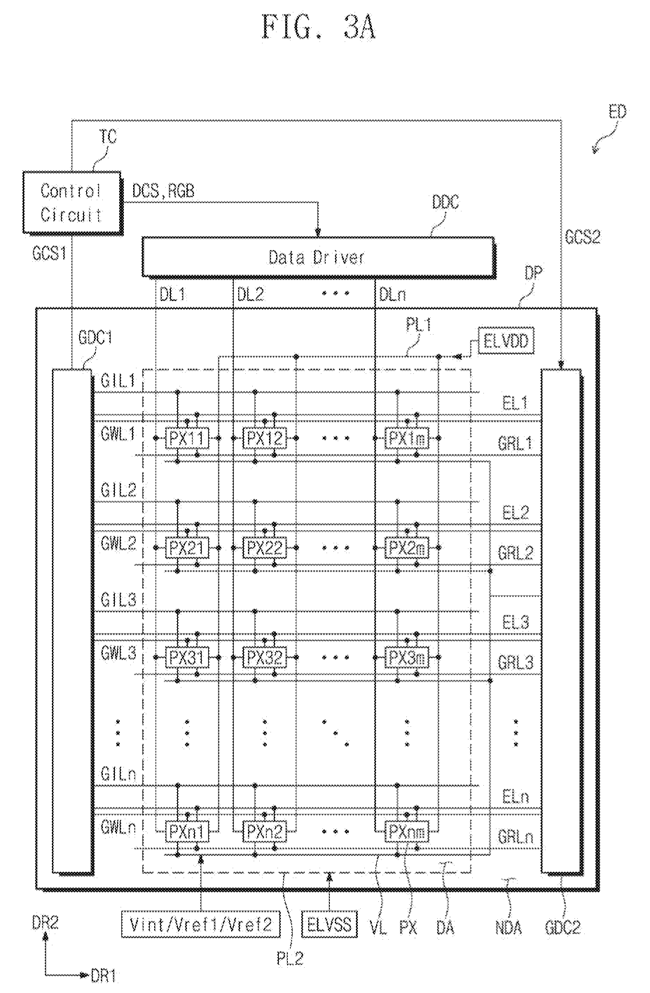

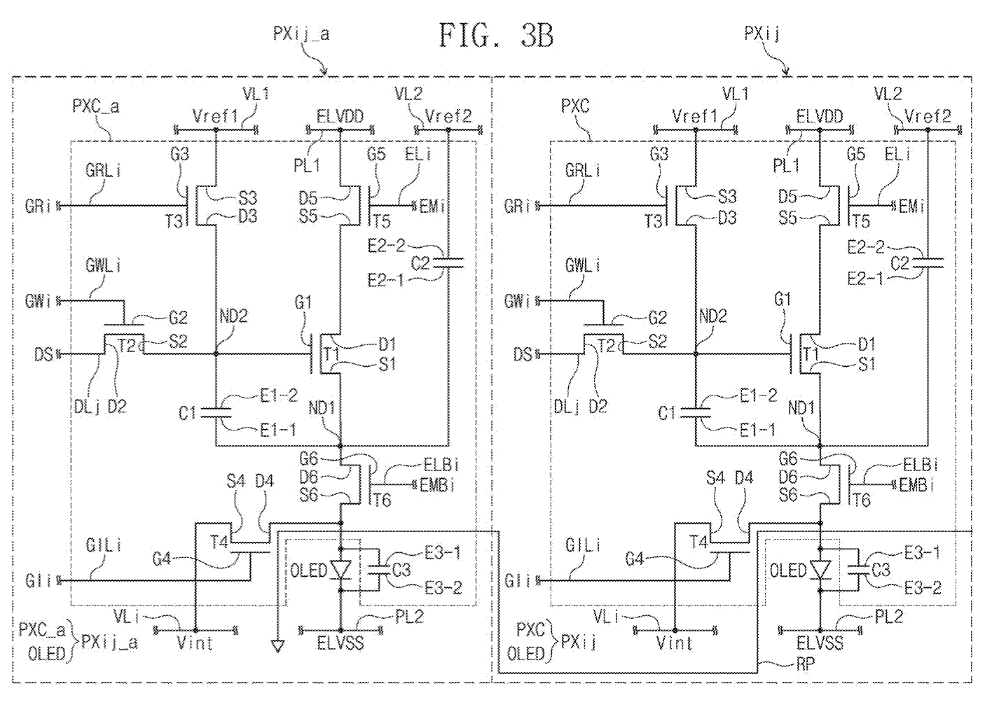

The electronic device ED may include a display area DA and a non-display area NDA. Pixels PX11 to PXnm (see FIG. 3A) are disposed in the display area DA, and pixels PX11 to PXnm (see FIG. 3A) are not disposed in the non-display area NDA. The non-display area NDA is defined along a periphery of the display surface DP-IS. The non-display area NDA may surround the display area DA. In one or more embodiments of the present disclosure, the non-display area NDA may be omitted or may be disposed only on one side of the display area DA.

Referring to FIG. 2B, an electronic device ED-1 according to one or more embodiments may be curved along the first direction DR1 with respect to an imaginary axis AX that extends in the second direction DR2. However, the present disclosure is not limited thereto, and the axis may be curved with respect to a plurality of axes that extend in the first direction DR1 or in different directions.

According to one or more embodiments, the electronic devices ED and ED-1 may be rollable, foldable, or sliding electronic devices. In this case, the electronic devices ED and ED-1 have flexible properties, and may be folded or rolled by a hinge member or a rolling member included in the housing. Accordingly, the electronic devices ED and ED-1 may include a curved display surface or a three-dimensional display surface DP-IS. The three-dimensional display surface DP-IS may include a plurality of display areas that indicate different directions.

According to one or more embodiments, unit pixels PXU that are arranged along the first direction DR1 and the second direction DR2 may be disposed on the display surface DP-IS. One unit pixel PXU may include at least two pixels PX11 to PXnm (see FIG. 3A) that generate a source light.

The light emission area size, shape, and arrangement of each of the pixels PX11 to PXnm (refer to FIG. 3A) included in one unit pixel PXU are not limited to any one. For example, the light emission area sizes of the pixels included in the unit pixel PXU may be different from each other. Furthermore, each emission area may have a circular or polygonal shape on a plane.

Referring to FIG. 2C, the electronic devices ED and ED-1 according to the present disclosure may include a display panel DP, a window panel WD disposed on the display panel DP, and a light control layer OSL that is disposed between the display panel DP and the window panel WD.

The display panel DP includes a base layer BS, a circuit element layer DP-CL that is disposed on the base layer BS, a display element layer DP-OLED, and an encapsulation layer TFE. The display panel DP may further include functional layers, such as a reflection prevention layer, and a refractive-index adjustment layer. The circuit element layer DP-CL includes at least a plurality of insulating layers and a circuit element. The insulating layers that will be described below may include an organic layer and/or an inorganic layer.

The base layer BS may include a synthetic resin film. The synthetic resin layer may include a thermosetting resin. In particular, the synthetic resin layer may include at least one of acrylate-based resin, methacrylate-based resin, polyisoprene, vinyl-based resin, epoxy-based resin, urethane-based resin, cellulose-based resin, siloxane-based resin, polyamide-based resin, and perylene-based resin. Besides, the base layer may include a glass substrate, a metal substrate, an organic/inorganic composite substrate, or the like.

An insulating layer, a semiconductor layer, and a conductive layer are formed in the circuit element layer DP-CL, through processes such as a coating process, a deposition process, and the like. Afterward, the insulating layer, the semiconductor layer, and the conductive layer may be selectively patterned through photolithography and etching processes. A semiconductor pattern, a conductive pattern, and a signal line are formed through the processes. Patterns disposed on the same layer are formed through the same process.

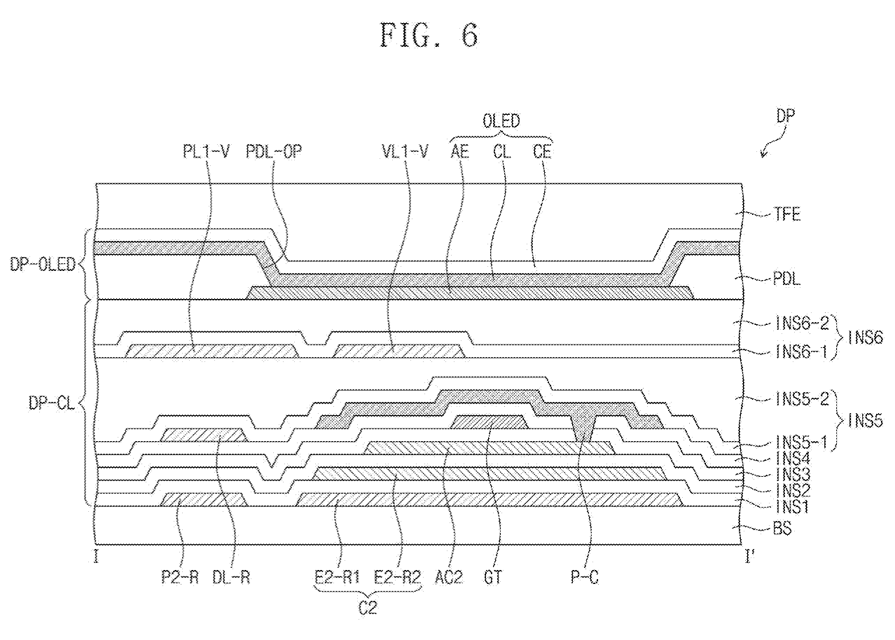

The circuit element layer DP-CL includes driving or signal lines that are connected to the pixels PX11 to PXnm (see FIG. 3A). These lines may include scan lines, data lines, and power lines to control the operation of each pixel. The display element layer DP-OLED may include a light emitting element OLED (see FIG. 6) and a pixel definition film PDL (see FIG. 6) for defining and separating the emission areas of each OLED.

The encapsulation layer TFE may be disposed on the display element layer DP-OLED to protect the light emitting element OLED (see FIG. 6) from environmental factors. The encapsulation layer TFE may include inorganic layers, and an organic layer that are disposed between the inorganic layers. The inorganic layers may protect the light emitting element OLED (see FIG. 6) from moisture and oxygen, and the organic layer may protect the light emitting element OLED (see FIG. 6) from a foreign material such as dust particles.

The light control layer OSL may include light control patterns that may convert the optical properties of the source light generated by the pixels PX11 to PXnm (see FIG. 3A). The light control patterns may include quantum dots that convert the wavelength of the emitted light, and may include color filters that selectively transmit light of certain wavelengths.

The window panel WD may be disposed on the display panel DP, and may transmit an image provided from the display panel DP, to the outside. The window panel WD may serve as a protective outermost layer through which the image is viewed. The window panel WD may divide the display area DA and the non-display area NDA of the display surface DP-IS as illustrated in FIG. 2A. A boundary between the display area DA and the non-display area NDA may be defined by a bezel pattern that is disposed under the window panel WD and absorbs light.

The window panel WD may include a base layer and functional layers that are disposed on the base layer. The functional layers may include a protective layer, an anti-fingerprint layer, and the like. The base layer of the window panel WD may be formed of glass, sapphire, or plastic.

FIG. 3A is a plan view of an electronic device according to one or more embodiments of the present disclosure. FIG. 3B is an equivalent circuit diagram of a repair pixel and a pixel according to one or more embodiments of the present disclosure.

Referring to FIG. 3A, the electronic device ED may include a display panel DP, first and second gate drivers GDC1 and GDC2, a data driver DDC, and a control circuit TC.

The control circuit TC controls driving of the first and second gate drivers GDC1 and GDC2 and the data driver DDC. The control circuit TC generates image data RGB by converting the data format of the input image signals to match the interface specification with the data driver DDC. The control circuit TC outputs the image data RGB and various control signals DCS, GCS1, and GCS2.

A first gate driver GDC1 receives a first gate control signal GCS1 from the control circuit TC, and a second gate driver GDC2 receives a second gate control signal GCS2 from the control circuit TC. The first gate control signal GCS1 may include a start signal for starting an operation of the first gate driver GDC1, a clock signal for determining when to output signals, and the like, and the second gate control signal GCS2 may include a start signal for starting an operation of the second gate driver GDC2, a clock signal for determining when to output signals, and the like.

The first and second gate drivers GDC1 and GDC2 output a plurality of scan signals to a plurality of scan lines GWL1 to GWLn, GRL1 to GRLn, and GIL1 to GILn that will be described later. Among the plurality of scan lines GWL1 to GWLn, GRL1 to GRLn, and GIL1 to GILn, a first group of scan lines GWL1 to GWLn may be referred to as write scan lines. Among the plurality of scan lines GWL1 to GWLn, GRL1 to GRLn, and GIL1 to GILn, a second group of scan lines GRL1 to GRLn may be referred to as reference scan lines. Among the plurality of scan lines GWL1 to GWLn, GRL1 to GRLn, and GIL1 to GILn, a third group of scan lines GIL1 to GILn may be referred to as initialization scan lines.

Furthermore, at least one of the first and second gate drivers GDC1 and GDC2 generates a plurality of emission control signals and outputs them to a plurality of emission signal lines EL1 to ELn.

The data driver DDC receives a data control signal DCS and an image data RGB from a control circuit TC. The data driver DDC converts the image data RGB into data signals and outputs the data signals to a plurality of data lines DL1 to DLm to be described later. The data signals are analog voltages corresponding to a gray value of the image data RGB. The data driver DDC may be a component that is included in the illustrated driving chip.

The display panel DP includes a plurality of scan lines GWL1 to GWLn, GRL1 to GRLn, and GIL1 to GILn, a plurality of emission signal lines EL1 to ELn, a plurality of data lines DL1 to DLm, and a plurality of pixels PX.

The plurality of scan lines GWL1 to GWLn, GRL1 to GRLn, and GIL1 to GILn extend in the first direction DR1, and are arranged in the second direction DR2 that is perpendicular to the first direction DR1. Each of the plurality of emission signal lines EL1 to ELn may be arranged parallel to a corresponding one of the plurality of scan lines GWL1 to GWLn, GRL1 to GRLn, and GIL1 to GILn. The plurality of data lines DL1 to DLm cross the plurality of scan lines GWL1 to GWLn, GRL1 to GRLn, and GIL1 to GILn to be insulated therefrom.

Each of the plurality of pixels PX is connected to a corresponding one of the plurality of scan lines GWL1 to GWLn, GRL1 to GRLn, and GIL1 to GILn, a corresponding one of the plurality of emission signal lines EL1 to ELn, and corresponding ones of the plurality of data lines DL1 to DLm.

The display panel DP receives a first power voltage ELVDD and a second power voltage ELVSS. The first power voltage ELVDD may be provided to a plurality of pixels PX through a first power line PL1. The second power voltage ELVSS may be provided to the plurality of pixels PX through the second power line PL2 disposed on the display panel DP.

The display panel DP may further receive an initialization voltage Vint and first and second reference voltages Vref1 and Vref2. The initialization voltage Vint and the first and second reference voltages Vref1 and Vref2 may be provided to the plurality of pixels PX through an initialization line VL and first and second voltage lines VL1 and VL2 (see FIG. 3B).

FIG. 3B illustrates a pixel PXij that is connected to an i-th write scan line GWLi, among the write scan lines GWL1 to GWLn (see FIG. 3A), and a j-th data line DLj that is connected to a j-th data line DLj, among the plurality of data lines DL1 to DLm (see FIG. 3A). The pixel PXij is connected to an i-th reference scan line GRLi, among reference scan lines GRL1 to GRLn (see FIG. 3A), and is connected to an i-th initialization scan line GILi, among initialization scan lines GIL1 to GILn (see FIG. 3A).

The pixel PXij may include a pixel circuit (or a pixel circuit PXC) and a light emitting element OLED that is electrically connected to the pixel circuit PXC. In one or more embodiments, the pixel circuit PXC may include six transistors (hereinafter, first to sixth transistors T1 to T6) and three capacitors (hereinafter, a first capacitor C1, a second capacitor C2, and a third capacitor C3). In one or more embodiments, the first to sixth transistors T1 to T6 may be transistors of a first type (e.g., an N-type). In one or more embodiments of the present disclosure, at least one of the first to sixth transistors T1 to T6 may be omitted from the pixel PXij, or an additional transistor may be further included in the pixel PXij.

According to one or more embodiments, each of first and second transistors T1 and T2 may include two gates (e.g., an upper gate and a lower gate). Furthermore, at least one of the first and second transistors T1 and T2 may include only one gate.

In one or more embodiments, the first transistor T1 may be referred to as a driving transistor, and the second transistor T2 may be referred to as a switching transistor. A node, to which the first transistor T1 and the light emitting element OLED are connected, may be referred to as a first node ND1, and a node, to which the first transistor T1 and the second transistor T2 are connected, may be referred to as a second node ND2.

The light emitting element OLED includes a first electrode that is electrically connected to the first node ND1, a second electrode that is connected to a second power line PL2 that receives the first power voltage ELVSS, and an emission layer that is disposed between the first electrode and the second electrode. A detailed description of the light emitting element OLED will be described later.

The first transistor T1 is electrically connected to the first power line PL1 that receives the second power voltage ELVDD and the first node ND1 therebetween. The first transistor T1 may include a source S1 that is connected to the first node ND1, a drain D1, a semiconductor area, and a gate G1 that is electrically connected to the second node ND2. According to one or more embodiments, the first transistor T1 may further include a lower gate that is connected to the first node ND1. In the present specification, a “source/drain/semiconductor area” included in the transistor may be one that is obtained by dividing a “semiconductor pattern” along an area.

The second transistor T2 is electrically connected to the j-th data line DLj and the second node ND2 therebetween. The second transistor T2 may include a source S2 that is connected to the second node ND2, a drain D2 that is connected to the j-th data line DLj, a semiconductor area, and a gate G2 that is connected to the i-th write scan line GWLi. According to one or more embodiments, the second transistor T2 may further include a lower gate that is electrically connected to the gate G2.

The third transistor T3 is electrically connected to the second node ND2 and the first voltage line VL1 that receives the first reference voltage Vref1 therebetween. The third transistor T3 may include a drain D3 that is connected to the second node ND2, a source S3 that is connected to the first voltage line VL1, a semiconductor area, and a gate G3 that is connected to the i-th reference scan line GRLi. According to one or more embodiments, the third transistor T3 may further include a lower gate that is electrically connected to the third upper gate G3.

The fourth transistor T4 is electrically connected to the initialization line VL that receives the initialization voltage Vint and the light emitting element OLED. The fourth transistor T4 may include a drain D4 that is connected to a first electrode of the light emitting element OLED, a source S4 that is connected to the initialization line VL, a semiconductor area, and a gate G4 that is connected to the i-th initialization scan line GILI. According to one or more embodiments, the fourth transistor T4 may further include a lower gate that is electrically connected to the gate G4.

The fifth transistor T5 is electrically connected to the first power line PL1 and the drain D1 of the first transistor T1 therebetween. In one or more embodiments, the fifth transistor T5 may include a drain D5 that is connected to the first power line PL1, a source S5 that is connected to the drain D1 of the first transistor T1, a semiconductor area, and a gate G5 that is connected to the i-th first emission signal line ELi. The fifth transistor T5 may further include a lower gate that is electrically connected to the gate G5.

The sixth transistor T6 is electrically connected to the first node ND1 and the light emitting element OLED therebetween. In one or more embodiments, the sixth transistor T6 may include a drain D6 that is connected to the first node ND1, a source S6 that is connected to the first electrode of the light emitting element OLED, a semiconductor area, and a gate G6 that is connected to the i-th second emission signal line ELBi. The sixth transistor T6 may further include a lower gate that is electrically connected to the gate G6.

The first capacitor C1 is electrically connected to the first node ND1 and the second node ND2 therebetween. The first capacitor C1 includes a (1-1)-th capacitor pattern E1-1 that is connected to the first node ND1 and a (1-2)-th capacitor pattern E1-2 that is connected to the second node ND2.

The second capacitor C2 is electrically connected to the second voltage line VL2 and the first node ND1 therebetween. The second capacitor C2 includes a (2-1)-th capacitor pattern E2-1 that is connected to the first node ND1 and a (2-2)-th capacitor pattern E2-2 that is connected to the second voltage line VL2.

The third capacitor C3 is electrically connected to the first electrode and the second electrode of the light emitting element OLED therebetween. The third capacitor C3 includes a first capacitor pattern E3-1 that is connected to the first electrode of the light emitting element OLED and a second capacitor pattern E3-2 that is connected to the second electrode of the light emitting element OLED.

According to one or more embodiments, any one of the first to third capacitors C1, C2, and C3 may be omitted.

The display panel DP according to the present disclosure may include a pixel PXij that is disposed in a display area DA (an active area) and a repair pixel PXij_a that is disposed in a non-display area NDA (a peripheral area). The repair pixel PXij_a may include a repair pixel circuit (or a pixel driver) PXC_a and a light emitting element OLED that is electrically connected to the repair pixel circuit PXC_a. The repair pixel circuit PXC_a included in the repair pixel PXij_a and the pixel circuit PXC included in the pixel PXij may have the same structure. For example, the repair pixel circuit PXC_a may also include the first to sixth transistors T1 to T6 and the first to third capacitors C1, C2, and C3 described above. Although the transistors included in the pixel circuit may have the same structure as those in the repair pixel circuit, they may be referred to differently for clarity, such that the transistors in the pixel circuit are referred to as pixel transistors, while those in the repair pixel circuit are referred to as repair transistors. According to one or more embodiments, the repair pixel PXij_a may not include the light emitting element OLED, and may include only the repair pixel circuit PXC_a disposed in the non-display area NDA, and the present disclosure is not limited to any one embodiment.

The repair pixel PXij_a may be configured to drive the light emitting element OLED of a defective pixel PXij by connecting the light emitting element OLED of the defective pixel PXij to the repair pixel circuit PXC_a. This connection is made when a defect is detected in any of the pixel circuits PXC during testing of the pixels PXij disposed in the display area DA. A defect, such as a dark spot, may occur in the pixel PXij having the defect.

The repair pixel PXij_a may be disposed in the non-display area NDA and may be connected to the defective pixel PXij in the display area DA via a repair line RP.

When a defect occurs in any one of the pixel circuits PXC, the connection between the light emitting element OLED and the defective pixel circuit PXC may be physically or electrically disconnected. In more detail, the disconnection may occur between the first electrode of the light emitting element OLED and the drain D4 of the fourth transistor T4, or between the first electrode of the light emitting element OLED and the source S6 of the sixth transistor T6. Accordingly, the defective pixel circuit PXC may not be driven.

Thereafter, the first electrode of the disconnected light emitting element OLED may be reconnected to the drain D4 of the fourth transistor T4 of the repair pixel PXij_a or the source S6 of the sixth transistor T6 through the repair line RP. Accordingly, the disconnected light emitting element (OLED) may be normally driven through the repair pixel circuit PXC_a having the same structure as that of the previous pixel circuit PXC.

According to the present disclosure, by including the repair pixel circuit PXC_a disposed in the non-display area NDA, it may be possible to repair defective pixels (e.g., pixels having dark spots) detected during the test process. Accordingly, it is possible to provide an electronic device with improved reliability and process yield rate.

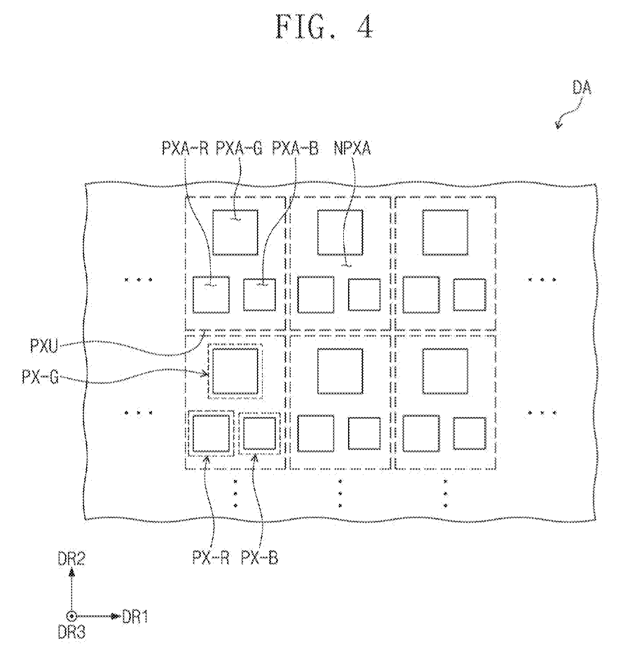

FIG. 4 is an enlarged plan view of a display area according to one or more embodiments of the present disclosure. The first to third pixels PX1, PX2, and PX3 that will be described below may correspond to the pixels PXij described in FIGS. 3A to 3B.

Referring to FIG. 4, a source light formed in the first pixel PX-R may be provided to the first emission area PXA-R, a source light formed in the second pixel PX-G may be provided to the second emission area PXA-G, and a source light formed in the third pixel PX-B may be provided to the third emission area PXA-B. Each of the first to third emission areas PXA-R, PXA-R, and PXA-B may correspond to an opening PDL-OP that is defined in the pixel definition film PDL (see FIG. 6). A non-emission area NPXA may be disposed between the first to third emission areas PXA-R, PXA-R, and PXA-B. The non-emission area NPXA may correspond to an area, in which the pixel definition film PDL (see FIG. 6) is disposed. The non-emission area NPXA may surround the first to third emission areas PXA-R, PXA-R, and PXA-B.

In FIG. 4, for convenience of description, the shapes (indicated by dotted lines) of the first electrodes AE (see FIG. 6) included in the first to third pixels PX-R, PX-G, and PX-B is referred to as first to third pixels PX-G, PX-R, and PX-B.

Each of the first to third pixels PX-R, PX-G, and PX-B includes a pixel circuit PXC (refer to FIG. 3B) and a light emitting element OLED (refer to FIG. 3B) connected thereto, and the light emitting elements OLED (refer to FIG. 3B) may generate a source light of the same color. For example, the source light may be blue. The source light generated by the light emitting elements OLED (see FIG. 3B) may be converted into any one of red, green, and blue through the light control patterns included in the light control layer OSL described in FIG. 2C.

The converted lights may be emitted through the first emission area PXA-R, the second emission area PXA-G, and the third emission area PXA-B. When the lights pass through the light control layer OSL, red light may be provided to the first emission area PXA-R, green light may be provided to the second emission area PXA-G, and blue light may be provided to the third emission area PXA-B. However, the present disclosure is not limited thereto, and the source lights generated by the first to third pixels PX-R, PX-G, and PX-B may have different colors.

According to one or more embodiments, the first emission area PXA-R and the third emission area PXA-B are disposed in the same row, and the second emission area PXA-G is disposed in a different row from the first emission area PXA-R and the third emission area PXA-B. For example, the first emission area PXA-R and the third emission area PXA-B may be spaced apart from each other in the first direction DR1, and the second emission area PXA-G may be spaced apart from the second emission area PXA-R and the third emission area PXA-B in a diagonal direction of the first direction DR1 and the second direction DR2.

According to one or more embodiments, an area size of the first emission area PXA-R may be less than an area size of the second emission area PXA-G and may be greater than an area size of the third emission area PXA-B.

In one or more embodiments, the first emission area PXA-R, the second emission area PXA-G, and the third emission area PXA-B having a square shape are illustrated by way of example, but the arrangement form and sizes of the emission areas are not limited thereto.

The disposition structure of the first emission area PXA-R, the second emission area PXA-G, and the third emission area PXA-B in the unit pixel PXU illustrated in FIG. 4 is only an example, and the present disclosure is not limited thereto. For example, the first emission area PXA-R, the second emission area PXA-G, and the third emission area PXA-B may be arranged along the first direction DR1, and may be disposed in the same row. Furthermore, the disposition of the first emission area PXA-R, the second emission area PXA-G, and the third emission area PXA-B of each of the unit pixels PXU does not necessarily have to be the same.

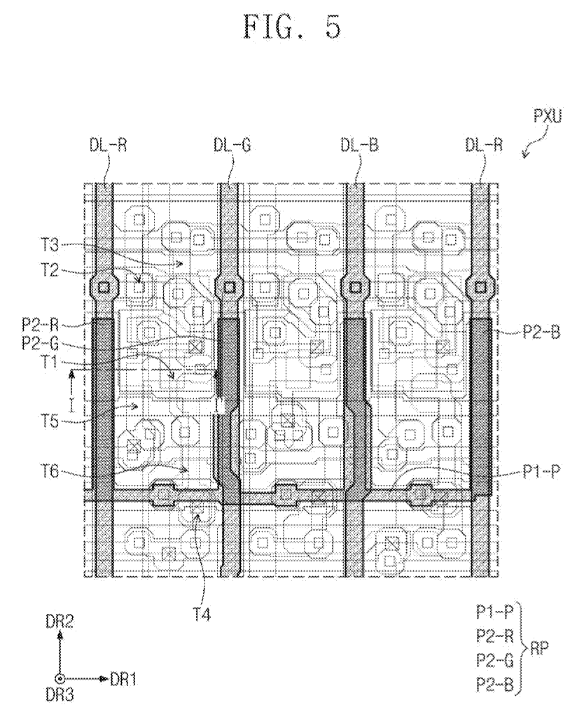

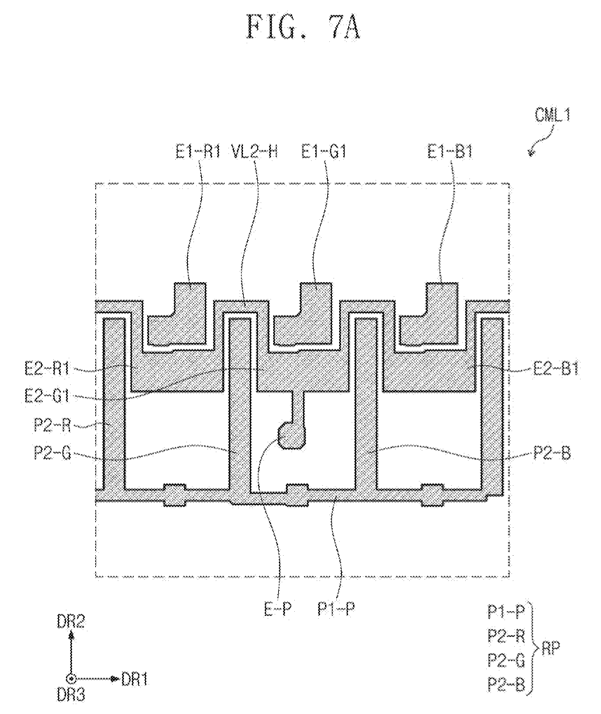

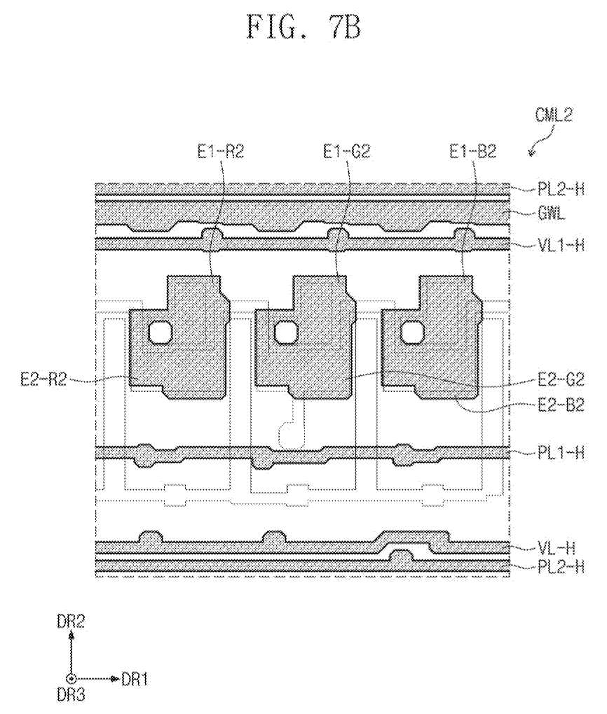

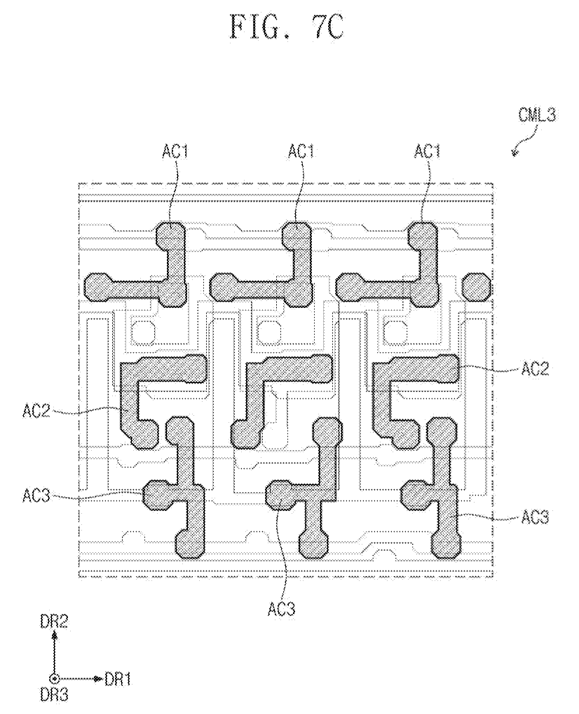

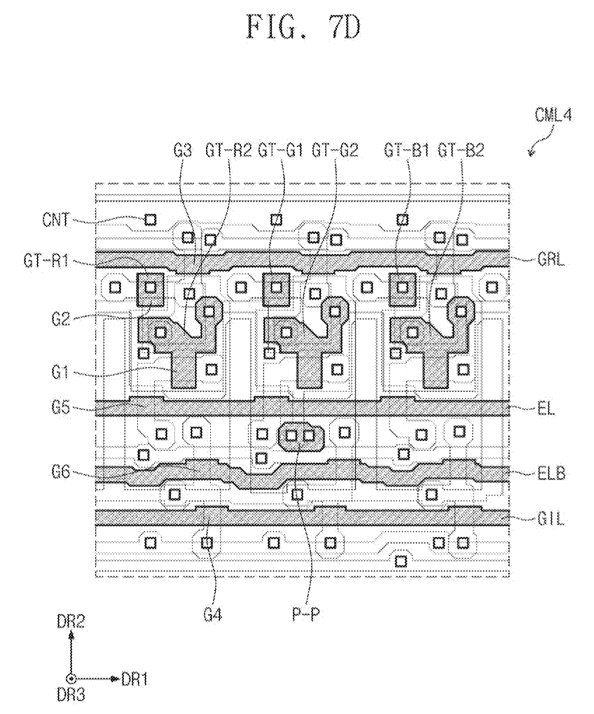

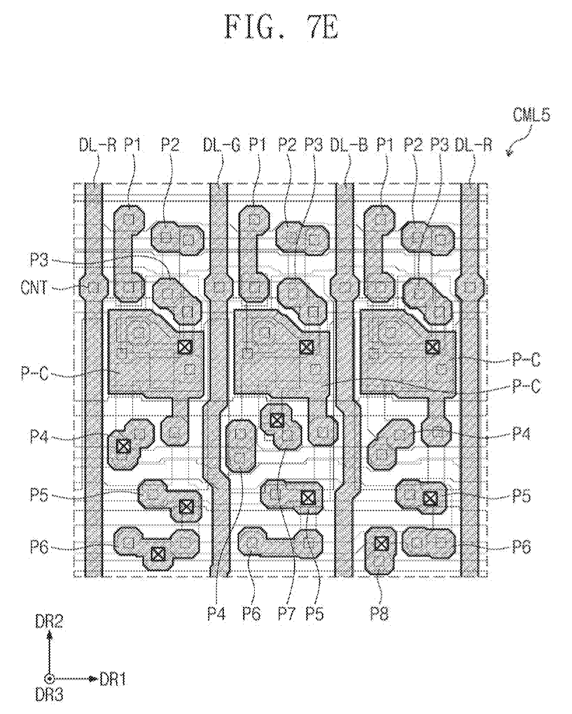

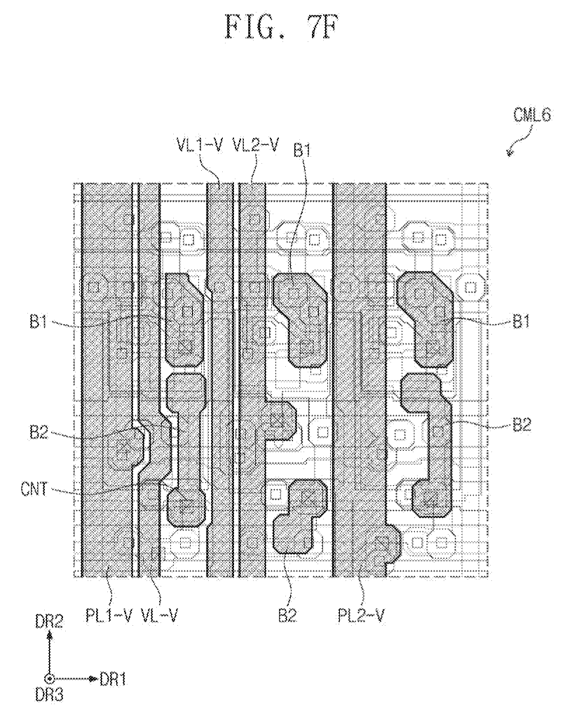

FIG. 5 is a plan view according to a stack order of conductive patterns included in a unit pixel according to one or more embodiments of the present disclosure. FIG. 6 is a cross-sectional view taken along line I-I’ of FIG. 5. FIGS. 7A to 7F are plan views illustrating a stack order of layers of conductive patterns included in a unit pixel for respective patterns according to one or more embodiments of the present disclosure.

Referring to FIG. 5, one unit pixel PXU may include first to third pixels PX-R, PX-G, and PX-B (see FIG. 4). Each of the first to third pixels PX-R, PX-G, and PX-B may include the pixel circuit PXC and the light emitting element OLED described in FIG. 3A. The first to third pixels PX-R, PX-G, and PX-B may be connected to the first and second power lines PL1 and PL2, the scan lines GWL, GRL, and GIL, the data lines DL-R, DL-G, and DL-B, the initialization line VL, the first and second voltage lines VL1 and VL2, and the first and second emission signal lines EL and ELB.

In FIG. 5, only the repair line RP and the data lines DL-R, DL-G, and DL-B are hatched.

According to the present disclosure, a portion of the repair line RP may overlap the data lines DL-R, DL-G, and DL-B. The data lines DL-R, DL-G, and DL-B may correspond to any one of the data lines DL1 to DLm described in FIGS. 3A to 3B.

The repair line RP may include a first part P1-P and second parts P2-R, P2-G, and P2-B. The first part P1-P may extend along the first direction DR1, and each of the second parts P2-R, P2-G, and P2-B may protrude from the first part P1-P along the second direction DR2. The first part P1-P and the second parts P2-R, P2-G, and P2-B are integral patterns that are formed through the same process, but will be described separately for convenience of description.

Referring to FIG. 6, the display panel DP according to one or more embodiments may include a base layer BS, a circuit element layer DP-CL that is disposed on the base layer BS, a display element layer DP-OLED, and an encapsulation layer TFE. As described in FIG. 2C, the electronic device ED may include a light control layer OSL and a window panel WD that is disposed on the display panel DP.

The circuit element layer DP-CL is disposed on the base layer BS. The circuit element layer DP-CL may include first to sixth insulating layers INS1 to INS6 that are disposed on the base layer BS, and conductive patterns P2-R, E2-R1, E2-R2, AC2, P-C, PL1-V, and VL1-V that are disposed between the first to sixth insulating layers INS1 to INS6. According to one or more embodiments, each of the first to fourth insulating layers INS1 to INS4 may be provided as an inorganic layer. The first to fourth insulating layers INS1 to INS4 may be provided as a single inorganic layer or may be provided as a multi-layer including different inorganic layers, and the present disclosure is not limited to any one embodiment.

The fifth insulating layer 50 may include a first inorganic layer INS5-1 and a first organic layer INS5-2. The sixth insulating layer 60 may include a first inorganic layer INS6-1 and a first organic layer INS6-2. The conductive patterns P2-R, E2-R1, E2-R2, AC2, P-C, PL1-V, and VL1-V disposed between the first to sixth insulating layers INS1 to INS6 will be described later.

The display element layer DP-OLED may include a pixel definition film PDL that defines an opening PDL-OP corresponding to each of the emission areas PXA-R, PXA-G, and PXA-B described in FIG. 4, and a light emitting element OLED. The light emitting element OLED illustrated in FIG. 6 may be included in the first pixel PX-R described in FIG. 4. The description of the light emitting element OLED may be commonly applied to the pixels PX-R, PX-G, and PX-B.

According to one or more embodiments, the pixel definition film PDL may have a property of absorbing light. For example, the pixel definition film PDL may have a black color. The pixel definition film PDL may include a black coloring agent. The black coloring agent may include a black dye and a black pigment. The black coloring agent may include carbon black, a metal such as chromium, or an oxide thereof. According to one or more embodiments, the pixel definition film PDL may correspond to a light shielding pattern having light shielding characteristics.

The light emitting element OLED may include a first electrode AE, a second electrode CE, and a common layer CL that is disposed between the first electrode AE and the second electrode CE.

The first electrode AE of the light emitting element OLED may be disposed on the sixth insulating layer INS6. The second electrode CE may be disposed on the first electrode AE. The common layer CL may be disposed between the first electrode AE and the second electrode CE. The common layer CL may include an emission layer including an organic material, a hole control layer that is disposed between the first electrode AE and the emission layer, and an electronic control layer that is disposed between the emission layer and the second electrode CE. The hole control layer may include a hole transport layer and a hole injection layer. The electron control layer may include an electron transport layer and an electron injection layer. According to one or more embodiments, the common layer CL and the second electrode CE may be a common layer that is provided as an integral pattern commonly formed on the first to third pixels PX-G, PX-R, and PX-B.

The encapsulation layer TFE may cover the display element layer DP-OLED. The encapsulation layer TFE may include an organic material or an inorganic material. The encapsulation layer TFE may have a multilayer structure, in which inorganic layers/organic layers are repeated. In one or more embodiments, the encapsulation layer TFE may include a first inorganic layer, an organic layer, and a second inorganic layer that are sequentially stacked. The first and second inorganic layers may protect the light emitting element OLED from external moisture, and the organic layer may prevent a stamping defect of the light emitting element OLED due to a foreign material introduced during a manufacturing process.

The first and second inorganic layers may include a silicon nitride layer, a silicon oxynitride layer, a silicon oxide layer, a titanium oxide layer, an aluminum oxide layer, or the like. Each of the first and second inorganic layers may have a multilayer structure. The organic layer may include an acrylic-based organic layer, but the present disclosure is not limited thereto. The inorganic layers may protect the light emitting element OLED from moisture and oxygen, and the organic layer may protect the light emitting element OLED from a foreign material such as dust particles.

The light control layer OSL described in FIG. 2C may be disposed on the encapsulation layer TFE. The light control layer OSL may be disposed between the encapsulation layer TFE and the window panel WD. A rear surface of the window panel WD may provide a base surface, on which components included in the light control layer OSL are formed.

The light control layer OSL according to one or more embodiments may include a color filter layer that is disposed on a rear surface of the window panel WD. The color filter layer may include a first color filter that transmits a first light, a second color filter that transmits a second light, and a third color filter that transmits a source light. In one or more embodiments, the first color filter may be a red filter, the second color filter may be a green filter, and the third color filter may be a blue filter.

Each of the first to third color filters includes a polymer photosensitive resin and a colorant. The first color filter may include a red colorant, the second color filter may include a green colorant, and the third color filter may include a blue colorant. The first color filter may include a red pigment or a red dye, the second color filter may include a green pigment or a green dye, and the third color filter may include a blue pigment or a blue dye.

The first to third color filters may be disposed to correspond to the first emission area PXA-R, the second emission area PXA-G, and the third emission area PXA-B described above with reference to FIG. 4, respectively. That is, each of the first to third color filters may overlap the opening PDL-OP of the corresponding pixel definition film PDL.

According to one or more embodiments, at least two of the first to third color filters may be stacked on the pixel definition film PDL. At least two color filters are disposed to overlap each other in the third direction DR3 that is a thickness direction, to distinguish boundaries between adjacent emission areas.

According to one or more embodiments, first to third light control patterns each including quantum dots may be disposed on the first to third color filters. Capping layers that seal the first to third color filters, and banks that distinguish the boundaries of the first to third light control patterns may be further included. The banks may overlap the pixel definition film PDL.

According to one or more embodiments, a low-refraction layer may be disposed between the first to third color filters and the first to third color filters. The low-refraction layer may include at least one inorganic layer. For example, the low-refraction layer may include silicon nitride, aluminum nitride, zirconium nitride, titanium nitride, hafnium nitride, tantalum nitride, silicon oxide, aluminum oxide, titanium oxide, tin oxide, cerium oxide, silicon oxynitride, or a metal thin film having a light transmittance. However, embodiments not limited thereto, and the low-refraction layer may include an organic film. For example, the low-refraction layer may have a structure, in which a plurality of hollow particles are dispersed in an organic polymer resin. The low-refraction layer may include a single layer or a plurality of layers.

A layer structure of any one of the first to third pixels PX-R, PX-G, and PX-B that will be described below may also be applied to the above-described repair pixel PX_a, and a repeated description thereof will be omitted.

Referring to FIGS. 5, 6, and 7A, a first conductive layer CML1 may be disposed on the base layer BS and may be covered by the first insulating layer INS1.

The first conductive layer CML1 includes a repair line RP, a (1-1)-th patterns E1-R1, E1-G1, and E1-B1 corresponding to the (1-1)-th capacitor pattern E1-1 included in the first capacitor C1 (see FIG. 3B), the (2-1)-th patterns E2-R1, E2-G1, and E2-B1 corresponding to the (2-1)-th capacitor pattern E2-1 included in the second capacitor C2 (see FIG. 3B), and a (2-1)-th voltage line VL1 included in the second voltage line VL2.

The (2-1)-th patterns E2-R1, E2-G1, and E2-B1 and the (2-1)-th voltage line VL2-H are integral patterns formed through the same process, but will be described separately for convenience of description.

The repair line RP may include a first part P1-P and second parts P2-R, P2-G, and P2-B. The first part P1-P may extend along the first direction DR1, and each of the second parts P2-R, P2-G, and P2-B may protrude from the first part P1-P along the second direction DR2. The first part P1-P and the second parts P2-R, P2-G, and P2-B are integral patterns that are formed through the same process, but will be described separately for convenience of description.

The patterns E1-R1, E1-G1, and E1-B1 may be spaced apart from each other in the first direction DR1. The (2-1)-th patterns E2-R1, E2-G1, and E2-B1 may be disposed between the (1-1)-th patterns E1-R1, E1-G1, and E1-B1 and the first part P1-P.

The (2-1)-th voltage line VL2-H may connect two adjacent (2-1)-th patterns E2-R1, E2-G1, and E2-B1 and may surround ends of the second parts P2-R, P2-G, and P2-B.

Among the (2-1)-th patterns E2-R1, E2-G1, and E2-B1, the (2-1)-th pattern E2-G1 disposed at the center thereof may include a protruding pattern E-P that protrudes along the second direction DR2. The protruding pattern E-P may be connected to the connection protruding pattern P-P included in the fourth conductive layer CML4.

Referring to FIGS. 5, 6 and 7B, a second conductive layer CML2 may be disposed on the first insulating layer INS1 and may be covered by the second insulating layer INS2.

The second conductive layer CML2 includes a write scan line GWL, a (1-1)-th voltage line VL1-H included in the first voltage line VL1, (1-2)-th patterns E1-R2, E1-G2, and E1-B2 corresponding to (1-2)-th capacitor pattern E1-2 included in the first capacitor C1 (see FIG. 3B), (2-2)-th patterns E2-R2, E2-G2, and E2-B2 corresponding to the (1-2)-th capacitor pattern E2-2 included in the second capacitor C2 (see FIG. 3B), a (1-1)-th power line PL1-H included in the first power line PL1, a (1-1)-th initialization line VL-H included in the initialization line VL, and a (2-1)-th power line PL2-H included in the second power line PL2.

The write scan line GWL, the (1-1)-th voltage line VL-H, the (1-1)-th power line PL1-H, the (1-1)-th initialization line VL-H, and the (2-1)-th power line PL2-H may extend along the first direction DR1 and may be spaced apart from each other along the second direction DR2.

Among the (1-2)-th patterns E1-R2, E1-G2, and E1-B2, and the (2-2)-th patterns E2-R2, E2-G2, and E2-B2, the (1-2)-th pattern E1-R2, the (2-2)-th pattern E2-R2, the (1-2)-th pattern E1-G2 and the (2-2)-th pattern E2-G2, and the (1-2)-th pattern E1-B2 and the (2-2)-th pattern E2-B2 may be integral patterns that are formed through the same process.

The (1-2)-th pattern E1-R2 and the (1-1)-th pattern E1-R1 may overlap each other to define the first capacitor C1 (see FIG. 3B) included in the first pixel PX-R (see FIG. 4), the (1-2)-th pattern E1-G2 and the (1-1)-th pattern E1-G1 may overlap each other to define the first capacitor C1 (see FIG. 3B) included in the second pixel PX-G (see FIG. 4), and the (1-2)-th pattern E1-B2 and the (1-1)-th pattern E1-B1 may overlap each other to overlap each other to define the first capacitor C1 (see FIG. 3B) included in the third pixel PX-B (see FIG. 4).

The (2-2)-th pattern E2-R2 and the (2-1)-th pattern E2-R1 may overlap each other to define the second capacitor C2 (see FIG. 3B) included in the first pixel PX-R (see FIG. 4), the (2-2)-th pattern E2-G2 and the (2-1)-th pattern E2-G1 may overlap each other to define the second capacitor C2 (see FIG. 3B) included in the second pixel PX-G (see FIG. 4), and the (2-2)-th pattern E2-B2 and the (2-1)-th pattern E2-B1 may overlap each other to overlap each other to define the second capacitor C2 (see FIG. 3B) included in the third pixel PX-B (see FIG. 4).

Referring to FIGS. 5, 6 and 7C, a third conductive layer CML3 may be disposed on the second insulating layer INS2 and may be covered by the third insulating layer INS3.

The third conductive layer CML3 may include semiconductor patterns AC1, AC2, and AC3 that are included in the first to sixth transistors T1 to T6 described in FIG. 3B. Each of the first to third pixels PX-R, PX-G, and PX-B may include three semiconductor patterns AC1, AC2, and AC3. The semiconductor patterns AC1, AC2, and AC3 may be divided into “source/drain/semiconductor areas” included in the first to sixth transistors T1 to T6 for each area.

Referring to FIGS. 5, 6 and 7D, the fourth conductive layer CML4 may be disposed on the third insulating layer INS3 and may be covered by the fourth insulating layer INS4. In FIG. 7D, contact holes CNT that are defined while passing through at least any one of the first to third insulating layers INS1 to INS3 are illustrated.

The conductive layer CML4 may include a reference scan line GRL, a first emission signal line EL, a second emission signal line ELB, an initialization scan line GIL, a connection protruding pattern P-P, and gate patterns GT-R1, GT-R2, GT-G1, GT-G2, GT-B1, and GT-B2.

Each of the reference scan line GRL, the first emission signal line EL, the second emission signal line ELB, and the initialization scan line GIL may extend along the first direction DR1 and may be arranged along the second direction DR2.

The gate patterns GT-R1, GT-R2, GT-G1, GT-G2, GT-B1, and GT-B2 may be disposed between the reference scan line GRL and the first emission signal line EL. The first pixel PX-R may include two gate patterns GT-R1 and GT-R2, the second pixel PX-G may include two gate patterns GT-G1 and GT-G2, and the third pixel PX-B may include two gate patterns GT-B1 and GT-B2.

Portions of the patterns included in the conductive layer CML4, which overlap the semiconductor patterns AC1, AC2, and AC3 included in the third conductive layer CML3, may be defined as gates included in the first to sixth transistors T1 to T6.

A portion of the first semiconductor pattern AC1, which overlaps the reference scan line GRL, may be defined as a gate G3 of the third transistor T3. A portion of the first semiconductor pattern AC1, which overlaps the first gate patterns GT-R1, GT-G1, and GT-B1, may be defined as a gate G2 of the second transistor T2.

A portion of the second semiconductor pattern AC2, which overlaps the second gate patterns GT-R2, GT-G2, and GT-B2, may be defined as a gate G1 of the first transistor T1. A portion of the second semiconductor pattern AC2, which overlaps the first emission signal line EL, may be defined as a gate G5 of the fifth transistor T5.

A portion of the third semiconductor pattern AC3, which overlaps the second emission signal line ELB, may be defined as a gate G6 of the sixth transistor T6. A portion of the third semiconductor pattern AC3, which overlaps the initialization scan line GIL, may be defined as a gate G4 of the fourth transistor T4.

One end of the connection protruding pattern P-P may be connected to the protruding pattern E-P of the first conductive layer CML1 through the contact hole CNT, and an opposite end of the connection protruding pattern P-P may be connected to the seventh connection pattern P7 included in a fifth conductive layer CML5 through the contact hole CNT.

Referring to FIGS. 5, 6 and 7E, the fifth conductive layer CML5 may be disposed on the fourth insulating layer INS4 and may be covered by the fifth insulating layer INS5.

The fifth conductive layer CML5 may include first to third data lines DL-R, DL-G, and DL-B and connection patterns P-C and P1-P8 that connect patterns disposed in different conductive layers.

The first to third data lines DL-R, DL-G, and DL-B may extend along the second direction DR2, and may be spaced apart from each other along the first direction DR1. Each of the first to third pixels PX-R, PX-G, and PX-B may include connection patterns P-C and P1 to P8 that are disposed between two data lines disposed adjacent to each other along the first direction DR1.

Each of the first to third data lines DL-R, DL-G, and DL-B may be connected to the first semiconductor pattern AC1 through a contact hole CNT. Accordingly, each of the first to third data lines DL-R, DL-G, and DL-B may be connected to the second transistor T2.

The first connection pattern P1 may connect the write scan line GWL and a portion of the first semiconductor pattern AC1 through the contact holes CNT.

The second connection pattern P2 may connect the (1-1)-th voltage line VL1-H and another portion of the first semiconductor pattern AC1 through the contact holes CNT.

The third connection pattern P3 may connect the second gate patterns GT-R2, GT-G2, and GT-B2 and another portion of the first semiconductor pattern AC1 through the contact holes CNT.

The fourth connection pattern P4 may connect the (1-1)-th power line PL1-H and another portion the second semiconductor pattern AC2 through the contact holes CNT.

The fifth connection pattern P5 may connect another portion of the second semiconductor pattern AC2 and the second bridge patterns B2 included in a sixth conductive layer CML6 through the contact holes CNT.

The sixth connection pattern P6 may connect the (1-1)-th initialization line VL-H and a portion the third semiconductor pattern AC3 through the contact holes CNT.

The seventh connection pattern P7 may connect the connection protruding pattern P-P and the (2-2)-th voltage line VL2-V included in the sixth conductive layer CML6 through the contact holes CNT.

The eighth connection pattern P8 may connect the (2-1)-th power line PL2-H and the (2-2)-th power line PL2-V of the sixth conductive layer CML6 through the contact holes CNT.

The connection pattern P-C may be connected to the first bridge patterns B1 included in the sixth conductive layer CML6 through the contact hole CNT.

According to the present disclosure, the second voltage line VL2 may include a (2-1)-th voltage line VL2-H and a (2-2)-th voltage line VL2-V. The (2-1)-th voltage line VL2-H and the (2-2)-th voltage line VL2-V may be connected to each other through a protruding pattern E-P, a connection protruding pattern P-P, and a seventh connection pattern P7. Because the second voltage line VL2 has dual line structures that are disposed on different layers, a resistance of the second voltage line VL2 may be reduced.

Referring to FIGS. 5, 6, and 7F, the sixth conductive layer CML6 may be disposed on the fifth insulating layer INS5 and may be covered by the sixth insulating layer INS6.

The sixth conductive layer CML6 may include a (1-2)-th power line PL1-V included in the first power line PL1, a (1-2)-th initialization line VL-V included in the initialization line VL, first and second bridge patterns B1 and B2, a (1-2)-th voltage line VL1-V included in the first voltage line VL1, a (2-2)-th voltage line VL2-V included in the second voltage line VL2, and a (2-2)-th power line PL2-V included in the second power line PL2.

The (1-2)-th power line PL1-V, the (1-2)-th initialization line VL-V, the (1-2)-th voltage line VL1-V, the (2-2)-th voltage line VL2-V, and the (2-2)-th power line PL2-V may extend along the second direction DR2 and may be spaced apart from each other along the first direction DR1. The first and second bridge patterns B1 and B2 may be included in each of the first to third pixels PX-R, PX-G, and PX-B, and may be spaced apart from each other between the (1-2)-th initialization line VL-V and the (1-2)-th voltage line VL1-V along the second direction DR2.

The (1-2)-th power line PL1-V may be connected to the (1-1)-th power line PL1-H through the fourth connection pattern P4. Accordingly, because the first power line PL1 has dual line structures that are disposed on different layers, a resistance of the first power line PL1 may be reduced.

The (1-2)-th initialization line VL-V may be connected to the (1-1)-th initialization line VL-H through the fourth connection pattern P4. Accordingly, because the initialization line VL has dual line structures that are disposed on different layers, a resistance of the initialization line VL may be reduced.

The (2-2)-th voltage line VL2-V may be connected to the (2-1)-th voltage line VL2-H through the seventh connection pattern P7. Because the second voltage line VL2 has a dual line structure disposed on different layers, the resistance of the second voltage line VL2 may be reduced.

The (2-2)-th power line PL2-V may be connected to the (2-1)-th power line PL2-H through the eighth connection pattern P8. Accordingly, the second power line PL2, which has dual line structures that are disposed across different layers, may exhibit reduced resistance.

The first bridge pattern B1 may be connected to the connection pattern P-C through the contact hole CNT, and the second bridge pattern B2 may be connected to the fifth connection pattern P5 through the contact hole CNT. The second bridge pattern B2 may be connected to the first electrode AE (see FIG. 6) included in the light emitting element OLED (see FIG. 3B).

According to the present disclosure, the second parts P2-R, P2-G, and P2-B of the repair line RP included in the first conductive layer CML1 may overlap the data lines DL-R, DL-G, and DL-B. Since the repair line RP is independent of the lines included in the pixel circuit PXC (refer to FIG. 3B), the coupling of the repair line RP to the data lines DL-R, DL-G, and DL-B may not affect the operation of the pixel PXij (refer to FIG. 3B). According to the present disclosure, a signal distortion phenomenon caused due to coupling to the power lines may be prevented or mitigated by shielding the data lines DL-R, DL-G, and DL-B with the repair line RP. Accordingly, it is possible to provide the electronic device with an improved reliability.

In one or more embodiments of the present disclosure, an electronic device may include a base layer including an active area and a peripheral area, pixels in the active area, each of the pixels including a pixel circuit, a repair pixel circuit in the peripheral area, data lines connected to the pixels, and a repair line connected to the repair pixel circuit and extending to the active area. A portion of the repair line may overlap the data lines.

The data lines may be arranged along a first direction, and the repair line may include: a first part extending along the first direction; and second parts protruding from the first part along a second direction that crosses the first direction. Each of the second parts may overlap the data lines.

The repair pixel circuit may include repair transistors, the pixel circuit may include pixel transistors, and the pixel transistors may have a same structure as the repair transistors.

A connection between a light emitting element and a pixel transistor in any one of the pixels may be disconnected.

The connection between the light emitting element and the pixel transistor may be rerouted via the repair line.

The electronic device may include: a first conductive layer, a second conductive layer, a third conductive layer, a fourth conductive layer, a fifth conductive layer, and a sixth conductive layer on the base layer; a first insulating layer, a second insulating layer, a third insulating layer, a fourth insulating layer, a fifth insulating layer, and a sixth insulating layer between the first to sixth conductive layers; and a first power line, a second power line, an initialization line, a first voltage line, a second voltage line, a write scan line, a reference scan line, an initialization scan line, a first emission signal line, and a second emission signal line connected to the pixel transistors and the repair transistors.

The first conductive layer may be directly on the base layer and may be covered by the first insulating layer. The first conductive layer may include the repair line, (1-1)-th capacitor patterns between the second parts, (2-1)-th capacitor patterns between the (1-1)-th capacitor patterns and the first part, and a (2-1)-th voltage line connected to the (2-1)-th capacitor patterns and defining one pattern.

The second conductive layer may be on the first insulating layer and may be covered by the second insulating layer. The second conductive layer may include: a (2-1)-th power line, the write scan line, a (1-1)-th voltage line, a (1-1)-th power line, and a first initialization line, each of which extends along the first direction and may be arranged along the second direction; and capacitor electrodes between the (1-1)-th voltage line and the (1-1)-th power line and spaced apart from each other along the first direction.

Each of the capacitor electrodes may include a (1-2)-th capacitor pattern and a (2-2)-th capacitor pattern connected to each other and defining one pattern, wherein the (1-1)-th capacitor pattern overlaps the (1-2)-th capacitor pattern to constitute a first capacitor, and wherein the (2-1)-th capacitor pattern overlaps the (2-2)-th capacitor pattern to constitute a second capacitor.

The third conductive layer may be on the second insulating layer and may be covered by the third insulating layer, and the third conductive layer may include semiconductor patterns included in each of the pixel transistors and the repair transistors.

The fourth conductive layer may be on the third insulating layer and may be covered by the fourth insulating layer. The fourth conductive layer may include: the reference scan line, the first emission signal line, the second emission signal line, and the initialization scan line, each of which extends along the first direction and may be arranged along the second direction; and gates, a portion of each of which overlaps a semiconductor layer and included in each of the pixel transistors and the repair transistors.

The fifth conductive layer may be disposed on the fourth insulating layer and may be covered by the fifth insulating layer, and the fifth conductive layer may include connection patterns connecting the data lines and included different conductive layers.

The sixth conductive layer may be on the fifth insulating layer and may be covered by the sixth insulating layer. The sixth conductive layer may include a (1-2)-th power line, a second initialization line, a (1-2)-th voltage line, a (2-2)-th voltage line, and a (2-2)-th power line, each of which extends along the second direction and may be arranged along the first direction.

The (1-2)-th power line, the (2-2)-th power line, the (1-2)-th voltage line, the (2-2)-th voltage line, and a second initialization line may be connected to the (1-1)-th power line, the (2-1)-th power line, the (1-1)-th voltage line, the (2-1)-th voltage line, and the first initialization line through contact holes passing through the second to fifth insulating layers, respectively, to constitute the first power line, the second power line, the first voltage line, the second voltage line, and the initialization line.

The pixel circuit may include a light emitting element. The light emitting element may include a first electrode, a second electrode, and a common layer between the first electrode and the second electrode, and the common layer may include an emission layer.

The active area may include emission areas and non-emission areas, wherein, among the emission areas, three emission areas that may be directly adjacent to one another may be defined as one unit pixel, and wherein the active area may include a plurality of unit pixels including the one unit pixel, and the plurality of unit pixels may be arranged along a first direction and a second direction that intersect each other.

The three emission areas correspond to a first emission area, a second emission area, and a third emission area, wherein the first emission area may be configured to emit red light, the second emission area may be configured to emit green light, and the third emission area may be configured to emit blue light, and wherein a size of the first emission area may be less than a size of the second emission area, and may be greater than a size of the third emission area.

The first emission area and the third emission area may be spaced apart from each other along the first direction, and the second emission area may be spaced apart from each of the first emission area and the third emission area along a diagonal direction.

The pixel circuit may include a light emitting element, and the electronic device may further include: an encapsulation layer covering the light emitting element.

The electronic device may further include: light control patterns on the encapsulation layer, configured to convert optical properties of a source light generated in the light emitting element, and including quantum dots; and color filters on the light control patterns.

According to one or more embodiments of the present disclosure, as the data lines are shielded by a portion of the repair line, a signal distortion phenomenon due to coupling to the power lines may be prevented. Accordingly, it is possible to provide the electronic device with an improved reliability.

Although one or more embodiments of the present disclosure has been described for illustrative purposes, those skilled in the art will appreciate that various modifications, and substitutions are possible, without departing from the scope and spirit of the present disclosure as disclosed in the accompanying claims.

Accordingly, the technical scope of the present disclosure should not be limited to the contents described in the detailed description of the specification but should be defined by the claims.

What is claimed is:

1. An electronic device comprising:
a base layer including an active area and a peripheral area;
pixels in the active area, each of the pixels including a pixel circuit;
a repair pixel circuit in the peripheral area;
data lines connected to the pixels; and
a repair line connected to the repair pixel circuit and extending to the active area,
wherein a portion of the repair line overlaps the data lines.

2. The electronic device of claim 1, wherein the data lines are arranged along a first direction, and wherein the repair line includes:
a first part extending along the first direction; and
second parts protruding from the first part along a second direction that crosses the first direction, and
wherein each of the second parts overlaps the data lines.

3. The electronic device of claim 1, wherein the repair pixel circuit includes repair transistors, the pixel circuit includes pixel transistors, and the pixel transistors have a same structure as the repair transistors.

4. The electronic device of claim 1, wherein a connection between a light emitting element and a pixel transistor in any one of the pixels is disconnected.

5. The electronic device of claim 4, wherein the connection between the light emitting element and the pixel transistor is rerouted via the repair line.

6. The electronic device of claim 2, wherein the repair pixel circuit includes repair transistors, and the pixel circuit includes pixel transistors, and
wherein the electronic device further comprises:
a first conductive layer, a second conductive layer, a third conductive layer, a fourth conductive layer, a fifth conductive layer, and a sixth conductive layer on the base layer;
a first insulating layer, a second insulating layer, a third insulating layer, a fourth insulating layer, a fifth insulating layer, and a sixth insulating layer between the first to sixth conductive layers; and
a first power line, a second power line, an initialization line, a first voltage line, a second voltage line, a write scan line, a reference scan line, an initialization scan line, a first emission signal line, and a second emission signal line connected to the pixel transistors and the repair transistors.

7. The electronic device of claim 6, wherein the first conductive layer is directly on the base layer and is covered by the first insulating layer, and
wherein the first conductive layer includes the repair line, (1-1)-th capacitor patterns between the second parts, (2-1)-th capacitor patterns between the (1-1)-th capacitor patterns and the first part, and a (2-1)-th voltage line connected to the (2-1)-th capacitor patterns and defining one pattern.

8. The electronic device of claim 7, wherein the second conductive layer is on the first insulating layer and is covered by the second insulating layer, and
wherein the second conductive layer includes
a (2-1)-th power line, the write scan line, a (1-1)-th voltage line, a (1-1)-th power line, and a first initialization line, each of which extends along the first direction and is arranged along the second direction, and
capacitor electrodes between the (1-1)-th voltage line and the (1-1)-th power line and spaced apart from each other along the first direction.

9. The electronic device of claim 8, wherein each of the capacitor electrodes includes a (1-2)-th capacitor pattern and a (2-2)-th capacitor pattern connected to each other and defining one pattern,
wherein the (1-1)-th capacitor pattern overlaps the (1-2)-th capacitor pattern to constitute a first capacitor, and
wherein the (2-1)-th capacitor pattern overlaps the (2-2)-th capacitor pattern to constitute a second capacitor.

10. The electronic device of claim 8, wherein the third conductive layer is on the second insulating layer and is covered by the third insulating layer, and
wherein the third conductive layer includes semiconductor patterns included in each of the pixel transistors and the repair transistors.

11. The electronic device of claim 9, wherein the fourth conductive layer is on the third insulating layer and is covered by the fourth insulating layer, and
wherein the fourth conductive layer includes
the reference scan line, the first emission signal line, the second emission signal line, and the initialization scan line, each of which extends along the first direction and is arranged along the second direction, and
gates, a portion of each of which overlaps a semiconductor layer and included in each of the pixel transistors and the repair transistors.

12. The electronic device of claim 10, wherein the fifth conductive layer is disposed on the fourth insulating layer and is covered by the fifth insulating layer, and
wherein the fifth conductive layer includes connection patterns connecting the data lines and different conductive layers.

13. The electronic device of claim 11, wherein the sixth conductive layer is on the fifth insulating layer and is covered by the sixth insulating layer, and
wherein the sixth conductive layer includes a (1-2)-th power line, a second initialization line, a (1-2)-th voltage line, a (2-2)-th voltage line, and a (2-2)-th power line, each of which extends along the second direction and is arranged along the first direction.

14. The electronic device of claim 12, wherein the (1-2)-th power line, the (2-2)-th power line, the (1-2)-th voltage line, the (2-2)-th voltage line, and a second initialization line are connected to the (1-1)-th power line, the (2-1)-th power line, the (1-1)-th voltage line, the (2-1)-th voltage line, and the first initialization line through contact holes passing through the second to fifth insulating layers, respectively, to constitute the first power line, the second power line, the first voltage line, the second voltage line, and the initialization line.

15. The electronic device of claim 1, wherein the pixel circuit includes a light emitting element, and
wherein the light emitting element includes a first electrode, a second electrode, and a common layer between the first electrode and the second electrode, and
wherein the common layer includes an emission layer.

16. The electronic device of claim 1, wherein the active area includes emission areas and non-emission areas,
wherein, among the emission areas, three emission areas that are directly adjacent to one another are defined as one unit pixel, and
wherein the active area includes a plurality of unit pixels including the one unit pixel, and the plurality of unit pixels are arranged along a first direction and a second direction that intersect each other.

17. The electronic device of claim 16, wherein the three emission areas correspond to a first emission area, a second emission area, and a third emission area,
wherein the first emission area is configured to emit red light, the second emission area is configured to emit green light, and the third emission area is configured to emit blue light, and
wherein a size of the first emission area is less than a size of the second emission area, and is greater than a size of the third emission area.

18. The electronic device of claim 17, wherein the first emission area and the third emission area are spaced apart from each other along the first direction, and
wherein the second emission area is spaced apart from each of the first emission area and the third emission area along a diagonal direction.

19. The electronic device of claim 1, wherein the pixel circuit includes a light emitting element, and the electronic device further includes:
an encapsulation layer covering the light emitting element.

20. The electronic device of claim 19, further comprising:
light control patterns on the encapsulation layer, configured to convert optical properties of a source light generated in the light emitting element, and including quantum dots; and
color filters on the light control patterns.
